(19) United States
(12) Patent Application Publication
(10) Pub. No.: US 2024/0373713 A1
(43) Pub. Date: Nov. 7, 2024

(54) DISPLAY DEVICE

(71) Applicant: Samsung Display Co., Ltd., Yongin-Si (KR)

(72) Inventors: HYEYUN HAN, Yongin-si (KR); WONKYU KWAK, Yongin-si (KR)

(21) Appl. No.: 18/599,218

(22) Filed: Mar. 8, 2024

(30) Foreign Application Priority Data
May 3, 2023 (KR) 10-2023-0057467

(51) Int. Cl. H10K 59/35; H10K 59/122; H10K 59/40

(52) U.S. Cl. CPC H10K 59/353; H10K 59/122; H10K 59/40; H10K 59/352

(57) ABSTRACT

Provided is a display device including a display panel including first to third emission regions, and an input sensing layer including a sensing unit having first to third openings defined therein. When viewed on a plane, the first emission region and the sensing unit are spaced apart from each other by a first distance in a first direction, the second emission region and the sensing unit are spaced apart from each other by a second distance less than the first distance, and the third emission region and the sensing unit are spaced apart from each other by a third distance less than the second distance. A first length of the first emission region in the first direction is less than a second length of the second emission region, and the second length is less than a third length of the third emission region.

### CROSS-REFERENCE TO RELATED APPLICATIONS

This U.S. non-provisional patent application claims priority under 35 U.S.C. § 119 of Korean Patent Application No. 10-2023-0057467, filed on May 3, 2023, the entire contents of which are hereby incorporated by reference.

### BACKGROUND

The present disclosure herein relates to a display device including an input sensing layer.

Multimedia devices such as televisions, mobile phones, tablets, navigation systems, and game machines include a display device that displays an image to users through a display screen. The display device may include a display panel that generates an image and an input sensor that senses a user's touch.

The display panel of the display device may include pixels having a predetermined configuration, and the configuration of the pixels may be designed in various ways according to the size and purpose of use of the display device. Light generated from the pixels may cause various optical phenomena such as resonance or interference, and the degree of occurrence of these optical phenomena may vary depending on the configuration of the pixels. In addition, these optical phenomena may affect the display quality of the display device.

### SUMMARY

The present disclosure provides a display device with improved display quality.

An embodiment of the inventive concept provides a display device including a display panel and an input sensing layer. The display panel includes first emission regions including a first emission region, second emission regions including a second emission region, and third emission regions including a third emission region. The first emission regions and the second emission regions are disposed alternately in a first direction. The third emission region is spaced apart from the first emission region and the second emission region in a second direction perpendicular to the first direction. The third emission regions are disposed along the first direction. The input sensing layer is disposed on the display panel and includes a sensing unit having a first opening, a second opening, and a third opening respectively exposing the first emission region, the second emission region, and the third emission region. When viewed on a plane, the first emission region and the sensing unit are spaced apart from each other by a first vertical distance in the first direction, the second emission region and the sensing unit are spaced apart from each other by a second vertical distance less than the first vertical distance in the first direction, and the third emission region and the sensing unit are spaced apart from each other by a third vertical distance less than the second vertical distance in the first direction. A first length of the first emission region in the first direction is less than a second length of the second emission region in the first direction, and the second length is less than a third length of the third emission region in the first direction.

In an embodiment, the first opening may have a first opening length in the first direction, the second opening may have a second opening length in the first direction, and the third opening may have a third opening length in the first direction. An absolute value of a difference between the first length and the first opening length may be less than an absolute value of a difference between the second length and the second opening length, and the absolute value of the difference between the second length and the second opening length may be less than an absolute value of a difference between the third length and the third opening length.

In an embodiment, an area of the third emission region may be larger than an area of the second emission region, and the area of the second emission region may be larger than an area of the first emission region.

In an embodiment, the sensing unit may include: a first horizontal sensing part disposed between the first emission region and the second emission region and extending in the first direction; a second horizontal sensing part disposed between adjacent third emission regions and extending in the first direction; a first vertical sensing part extending in the second direction and disposed between the first emission region and the third emission region; and a second vertical sensing part extending in the second direction and disposed between the second emission region and the third emission region, wherein the first horizontal sensing part may be closer to the second emission region than to the first emission region.

In an embodiment, the first vertical sensing part may be closer to the third emission region than the first emission region.

In an embodiment, the second vertical sensing part may be closer to the third emission region than the second emission region.

In an embodiment, a width of the first vertical sensing part in the second direction may be less than a width of the second vertical sensing part in the second direction.

In an embodiment, the first emission region, the second emission region, and the third emission region may respectively emit a first color light, a second color light, and a third color light, which are different from each other.

In an embodiment, a wavelength range of the third color light may be less than a wavelength range of the first color light and less than a wavelength range of the second color light.

In an embodiment of the inventive concept, a display device includes a display panel and an input sensing layer. The display panel includes first emission regions including a first emission region, second emission regions including a second emission region, and third emission regions including a third emission region. The first emission regions and the second emission regions are disposed alternately in a first direction. The third emission region is spaced apart from the first emission region and the second emission region in a second direction perpendicular to the first direction. The third emission regions are disposed along the first direction. The input sensing layer is disposed on the display panel and includes a sensing unit having a first opening, a second opening, and a third openings respectively exposing the first emission region, the second emission region, and the third emission region. When viewed on a plane, a ratio of an area of the first emission region to an area of the first opening is less than a ratio of an area of the second emission region to an area of the second opening, and the ratio of the area of the second emission region to the area of the second opening is less than a ratio of an area of the third emission region to an area of the third opening.

In an embodiment, the first emission region, the second emission region, and the third emission region may respectively emit a first color light, a second color light, and a third color light, which are different from each other.

In an embodiment, the first color light may be a red light, the second color light may be a green light, and the third color light may be a blue light.

In an embodiment, when viewed on a plane, the area of the first emission region may be less than the area of the second emission region, and the area of the second emission region may be less than the area of the third emission region.

In an embodiment of the inventive concept, a display device includes first emission regions, second emission regions, third emission regions, a non-emission region, a base substrate, a display element layer, and an input sensing layer. The first emission regions include a first emission region having a first area. The second emission regions include a second emission region having a second area larger than the first area. The second emission regions are disposed alternately with the first emission regions in a first direction. The third emission regions include a third emission region. The third emission region has a third area larger than the second area and is spaced apart from the first emission region and the second emission region in a second direction perpendicular to the first direction. The non-emission region is disposed between the first emission regions, the second emission regions, and the third emission regions. The display element layer includes a first light emitting layer, a second light emitting layer, and a third light emitting layer disposed on the base substrate and respectively corresponding to the first emission region, the second emission region, and the third emission region. The input sensing layer includes a sensing unit, which has a first opening, a second opening, and a third opening respectively corresponding to the first emission region, the second emission region, and the third emission region. The sensing unit is disposed to correspond to the non-emission region on the display element layer. When viewed on a cross section, the sensing unit is closer to the second light emitting layer than to the first light emitting layer, is closer to the third light emitting layer than to the second light emitting layer, and is closer to the third light emitting layer than to the first light emitting layer.

In an embodiment, a slope of a first tilted line which is an imaginary line extending from an edge portion of the first light emitting layer in a direction of the sensing unit adjacent to the edge portion of the first light emitting layer may be less than a slope of a second tilted line which is an imaginary line extending from an edge portion of the second light emitting layer in a direction of the sensing unit adjacent to the edge portion of the second light emitting layer.

In an embodiment, a slope of a second tilted line which is an imaginary line extending from an edge portion of the second light emitting layer in a direction of the sensing unit adjacent to the edge portion of the second light emitting layer may be less than a slope of a third tilted line which is an imaginary line extending from an edge portion of the third light emitting layer in a direction of the sensing unit adjacent to the edge portion of the third light emitting layer.

In an embodiment, a slope of a first tilted line which is an imaginary line extending from an edge portion of the first light emitting layer in a direction of the sensing unit adjacent to the edge portion of the first light emitting layer may be less than a slope of a third tilted line which is an imaginary line extending from an edge portion of the third light emitting layer in a direction of the sensing unit adjacent to the edge portion of the third light emitting layer.

In an embodiment, the first emission region may have a first length in the first direction, the second emission region may have a second length greater than the first length in the first direction, and the third emission region may have a third length greater than the second length in the first direction.

In an embodiment, the first opening may have a first opening length in the first direction, the second opening may have a second opening length in the first direction, and the third opening may have a third opening length in the first direction. An absolute value of a difference between the first length and the first opening length may be less than an absolute value of a difference between the second length and the second opening length, and the absolute value of the difference between the second length and the second opening length may be less than an absolute value of a difference between the third length and the third opening length.

In an embodiment, the first emission region may emit a red light, the second emission region may emit a green light, and the third emission region may emit a blue light.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is a perspective view of a display device according to an embodiment of the inventive concept.

FIG. 2 is a cross-sectional view of a display module according to an embodiment of the inventive concept.

FIG. 3 is a plan view of a display panel according to an embodiment of the inventive concept.

FIG. 4 is a cross-sectional view of the display panel according to an embodiment of the inventive concept.

FIG. 5 is a plan view of an input sensing layer according to an embodiment of the inventive concept.

FIGS. 6A, 6B, and 6C are enlarged plan views of a portion of the display device according to an embodiment of the inventive concept.

FIG. 7 is a cross-sectional view of the display device according to an embodiment of the inventive concept.

FIG. 8A is a graph illustrating a luminance ratio according to a viewing angle of the display device according to a comparative embodiment of the inventive concept.

FIG. 8B is a graph illustrating a luminance ratio according to a viewing angle of the display device according to an embodiment of the inventive concept.

### DETAILED DESCRIPTION

In accordance with the inventive concept, various modifications can be made, various forms can be used, and specific embodiments will be illustrated in the drawings and described in detail in the text. However, this is not intended to limit the inventive concept to a specific form disclosed, and it will be understood that all changes, equivalents, or substitutes which fall in the spirit and technical scope of the inventive concept should be included.

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the inventive concept. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to an embodiment of the inventive concept will be explained with reference to the accompanying drawings.

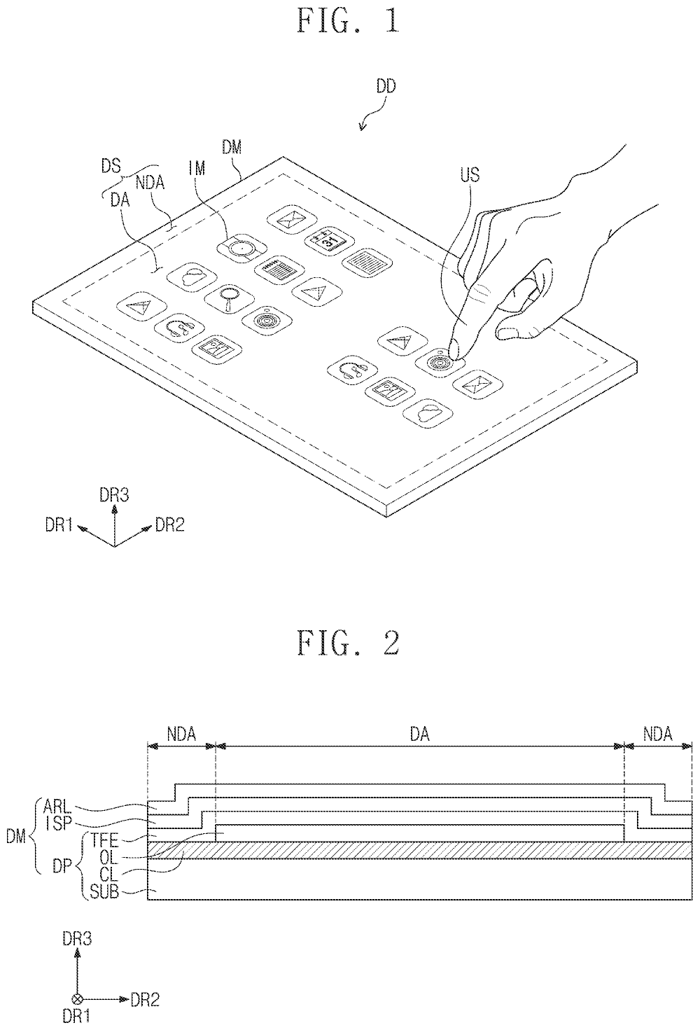

FIG. 1 is a perspective view of a display device DD according to an embodiment of the inventive concept.

Referring to FIG. 1, the display device DD according to an embodiment of the inventive concept may be activated according to an electrical signal and display an image IM. For example, the display device DD may be a large-sized device such as a television or an external billboard, or a small or medium-sized device such as a monitor, a mobile phone, a tablet, a navigation system, or a game machine. However, the embodiments of the display device DD described above are just examples and the inventive concept is not limited to any one embodiment as long as they do not depart from the concept of the inventive concept.

The display device DD may include a display module DM that displays the image IM and senses an external input. On a plane, the display module DM may have a rectangular shape with long sides extending in a first direction DR1 and short sides extending in a second direction DR2 crossing, e.g., perpendicular to, the first direction DR1. Without being limited thereto, however, the display module DM may have various shapes such as a circular shape or a polygonal shape.

In this embodiment, a third direction DR3 may be defined as a direction substantially perpendicular to a plane defined by the first and second directions DR1 and DR2. The front surface (or upper surface) and rear surface (or lower surface) of each member constituting the display device DD may be opposed to each other in the third direction DR3, and a normal direction of each of the front and rear surfaces may be substantially parallel to the third direction DR3. A separation distance between the front and rear surfaces defined along the third direction DR3 may correspond to the thickness of a member.

In this specification, the expression “on a plane” may be defined as a state viewed from the third direction DR3. In this specification, the expression “on a cross section” may be defined as a state viewed from the first direction DR1 or the second direction DR2. Meanwhile, directions indicated by the first to third directions DR1, DR2, and DR3 are relative concepts and may be converted into other directions.

The display device DD may be rigid or flexible. The term “flexible” means a property of being bendable, and a flexible structure may include everything from a completely foldable structure to a structure that can be bent to the level of several nanometers. For example, a flexible display device DD may include a curved device, a rollable device, a slidable device, or a foldable device.

The upper surface of the display module DM may be defined as a display surface DS, and the display surface DS may have a plane defined by the first direction DR1 and the second direction DR2. The display module DM may provide a user with the image IM generated through the display surface DS. The display surface DS may include a display region DA and a non-display region NDA.

The display region DA may display the image IM, and the non-display region NDA may not display the image IM. The non-display region NDA may be adjacent to the display region DA. For example, the non-display region NDA may surround the display region DA. The non-display region NDA may correspond to a region printed in a predetermined color and define a boundary of the display module DM.

The display module DM may sense an input applied from the outside of the display module DM. An external input may include various types of inputs such as force, pressure, temperature, or light. In this embodiment, the external input is illustrated as a user's hand US applied to the front surface of the display device DD. However, this is illustrated as an example, and the external input may include a touch by a pen or an input applied at a place close to the display device DD such as hovering.

FIG. 2 is a cross-sectional view of a display module DM according to an embodiment of the inventive concept.

Referring to FIG. 2, the display module DM may include a display panel DP, an input sensing layer ISP, and an anti-reflection layer ARL. The display panel DP may include a base substrate SUB, a circuit element layer CL, a display element layer OL, and a thin film encapsulation layer TFE.

The display panel DP according to an embodiment of the inventive concept may be a light-emitting display panel and is not particularly limited thereto. For example, the display panel DP may be an organic light-emitting display panel or an inorganic light-emitting display panel. A light emitting layer of the organic light-emitting display panel may contain an organic light-emitting material. A light emitting layer of the inorganic light-emitting display panel may contain quantum dots, quantum rods, and the like. Hereinafter, the display panel DP will be described as an organic light-emitting display panel.

The base substrate SUB may provide a base surface on which the circuit element layer CL is disposed. The base substrate SUB may be a rigid substrate or a flexible substrate capable of being bent, folded, or rolled. The base substrate SUB may be a glass substrate, a metal substrate, a polymer substrate, or the like. However, the embodiment of the inventive concept is not limited thereto, and the base substrate SUB may be an inorganic layer, an organic layer, or a composite material layer.

The base substrate SUB may have a multi-layered structure. For example, the base substrate SUB may include synthetic resin layers and a multi-layered or single-layered inorganic layer disposed between the synthetic resin layers. The synthetic resin layer may contain an acrylic-based resin, a methacrylic-based resin, polyisoprene, a vinyl-based resin, an epoxy-based resin, a urethane-based resin, a cellulose-based resin, a siloxane-based resin, a polyamide-based resin, a perylene-based resin, or the like. However, the material thereof is not particularly limited thereto.

The circuit element layer CL may be disposed on the base substrate SUB. The circuit element layer CL may include an insulating layer, a semiconductor pattern, and a conductive pattern. The insulating layer, the semiconductor pattern, and the conductive pattern, which are included in the circuit element layer CL, may form driving elements, signal lines, and pads in the circuit element layer CL.

The display element layer OL may be disposed on the circuit element layer CL. The display element layer OL may include light-emitting elements disposed in the display region DA. The light-emitting elements may include an organic light-emitting element, an inorganic light-emitting element, a micro LED, a nano LED, or the like and are not particularly limited thereto. The light-emitting elements of the display element layer OL are electrically connected to the driving elements of the circuit element layer CL and therefore may generate light in the display region DA according to signals provided by the driving elements.

The thin film encapsulation layer TFE may be disposed on the display element layer OL so as to seal the light-emitting elements. The thin film encapsulation layer TFE may include at least one thin film for improving the optical efficiency of the display element layer OL or protecting the display element layer OL. The thin film encapsulation layer TFE may include at least one of an inorganic layer or an organic layer.

The input sensing layer ISP may be disposed on the display panel DP. The input sensing layer ISP may be formed on the base surface provided by the display panel DP through a continuous process. The input sensing layer ISP may be disposed directly on the display panel DP without a separate adhesive layer. Without being limited thereto, however, the input sensing layer ISP may be coupled to the display panel DP by an adhesive layer.

The input sensing layer ISP may sense an external input and provide an input signal including the information about the external input so that the display panel DP may display an image corresponding to the external input. The input sensing layer ISP may be driven in various ways such as a capacitive method, a resistive film method, an infrared method, a sound wave method, or a pressure method, and the driving method of the input sensing layer ISP is not limited to any one embodiment as long as it can sense an external input. In this embodiment, the input sensing layer ISP will be described as an input sensing panel which is driven in a capacitive method.

The anti-reflection layer ARL may be disposed on the input sensing layer ISP. The anti-reflection layer ARL may be disposed directly on the input sensing layer ISP. Without being limited thereto, however, the anti-reflection layer ARL may be coupled to the input sensing layer ISP by a separate adhesive layer. The anti-reflection layer ARL may reduce the reflectance of external light incident from the outside of the display device DD, e.g., see FIG. 2.

In an embodiment of the inventive concept, the anti-reflection layer ARL may include a retarder and/or a polarizer. Each of the retarder and the polarizer may be provided as a film type or a liquid crystal coating type. The retarder and the polarizer may be provided in the form of one polarizing film.

In an embodiment of the inventive concept, the anti-reflection layer ARL may include color filters. The color filters may be disposed to correspond to the configuration and light-emitting colors of pixels included in the display panel DP. The color filters may filter external light incident from the outside into the same colors as those emitted by corresponding pixels. The anti-reflection layer ARL may further include a light blocking pattern disposed to be adjacent to the color filters.

Meanwhile, FIG. 2 illustrates an embodiment in which the input sensing layer ISP and the anti-reflection layer ARL are sequentially disposed on the display panel DP, but the embodiment of the inventive concept is not limited thereto. For example, the stacking order of the anti-reflection layer ARL and the input sensing layer ISP may be changed.

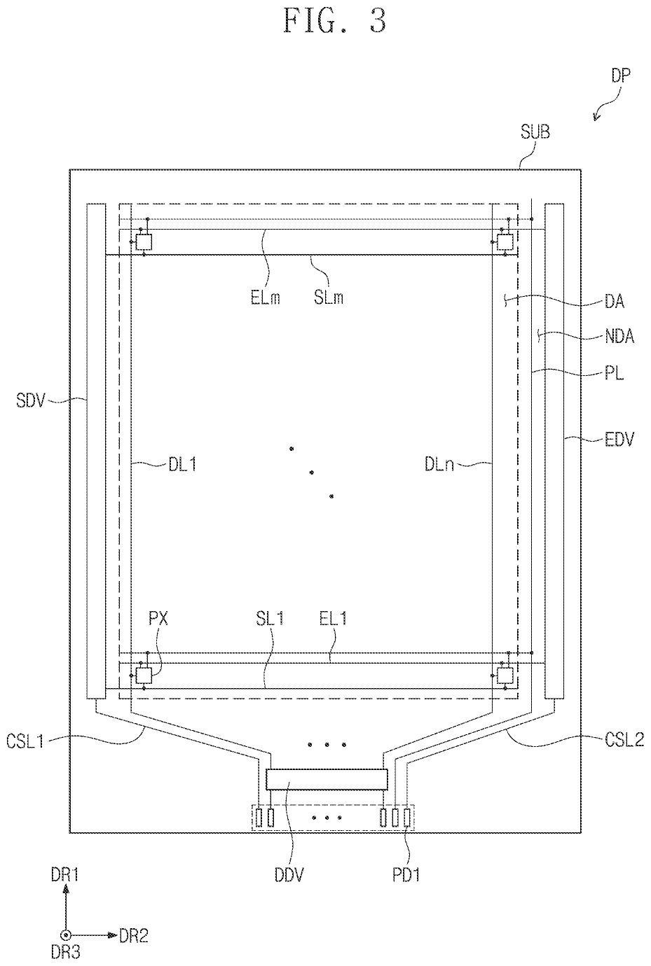

FIG. 3 is a plan view of a display panel DP according to an embodiment of the inventive concept.

Referring to FIG. 3, the display panel DP may include a base substrate SUB, pixels PX, signal lines SL1 to SLm, DL1 to DLn, EL1 to ELm, CSL1, CSL2, and PL electrically connected to the pixels PX, a scan driver SDV, a data driver DDV, and a light-emitting driver EDV.

On a plane parallel to each of the first and second directions DR1 and DR2, the base substrate SUB may provide a base surface on which the elements and lines of the display panel DP are disposed. The base substrate SUB may include the display region DA and non-display region NDA of the display panel DP, which are described above.

The display region DA may be a region in which the pixels PX are disposed to display an image. The non-display region NDA may be a region which is adjacent to the display region DA and does not display an image. The scan driver SDV, the data driver DDV, the light-emitting driver EDV, and the like for driving the pixels PX may be disposed in the non-display region NDA. In order to reduce the area of the non-display region NDA, however, at least one of the scan driver SDV, the data driver DDV, or the light-emitting driver EDV may be disposed in the display region DA.

Each of the pixels PX may include a pixel driving circuit, which is composed of transistors, e.g., a switching transistor, a driving transistor, etc., and at least one capacitor, and a light-emitting element electrically connected to the pixel driving circuit. Each of the pixels PX may display an image in the display region DA by emitting light in response to an electrical signal applied to the pixel PX. Some of the pixels PX may include a transistor disposed in the non-display region NDA, and the inventive concept is not limited to any one embodiment.

The signal lines SL1 to SLm, DL1 to DLn, EL1 to ELm, CSL1, CSL2, and PL may include scan lines SL1 to SLm, data lines DL1 to DLn, light-emitting lines EL1 to ELm, first and second control lines CSL1 and CSL2, and a power line PL, wherein m and n are natural numbers.

The data lines DL1 to DLn may be insulated from and cross the scan lines SL1 to SLm and the light-emitting lines EL1 to ELm on a plane. For example, the scan lines SL1 to SLm may extend in the second direction DR2 to be electrically connected to the scan driver SDV. The data lines DL1 to DLn may extend in the first direction DR1 to be electrically connected to the data driver DDV. The light-emitting lines EL1 to ELm may extend in the second direction DR2 to be electrically connected to the light-emitting driver EDV.

The power line PL may include a portion extending in the first direction DR1 and a portion extending in the second direction DR2. The portion of the power line PL extending in the first direction DR1 may be disposed in the non-display region NDA. The portion of the power line PL extending in the second direction DR2 may be electrically connected to the pixels PX and the portion of the power line PL extending in the first direction DR1. The portion of the power line PL extending in the second direction DR2 may be disposed on a layer different from that of the portion extending in the first direction DR1 and connected to the portion extending in the first direction DR1 through a contact hole. In an embodiment, the portion of the power line PL extending in the second direction DR2 and the portion thereof extending in the first direction DR1 may be disposed on the same layer as each other so as to have an integral shape with each other.

The first control line CSL1 may be electrically connected to the scan driver SDV. The second control line CSL2 may be electrically connected to the light-emitting driver EDV.

First pads PD1 may be disposed to be adjacent to the lower end of the non-display region NDA. The first pads PD1 may be disposed to be closer to the lower end of the display panel DP than the data driver DDV. The first pads PD1 may be spaced apart from each other along the second direction DR2.

The first pads PD1 may be defined as display pads electrically connected to the pixels PX. Each of the first pads PD1 may be connected to a corresponding signal line among the signal lines SL1 to SLm, DL1 to DLn, EL1 to ELm, CSL1, CSL2, and PL. For example, the first pads PD1 may be electrically connected to the power line PL, the first control line CSL1, the second control line CSL2, and the data lines DL1 to DLn, respectively.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The light-emitting driver EDV may generate light-emitting signals in response to a light-emitting control signal. The light-emitting signals may be applied to the pixels PX through the light-emitting lines EL1 to ELm.

The pixels PX may receive data voltages in response to scan signals. The pixels PX may generate an image by emitting light having luminance corresponding to the data voltages in response to light-emitting signals. The light-emitting time of the pixels PX may be controlled by the light-emitting signals.

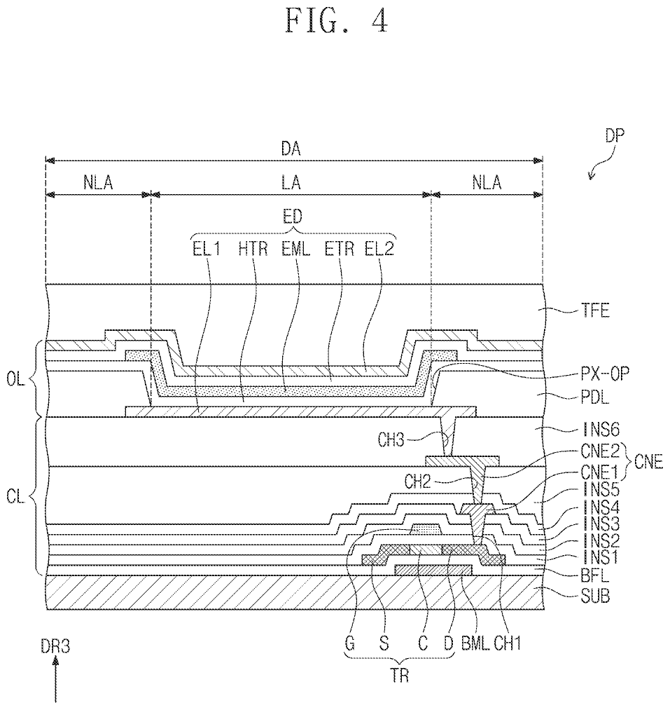

FIG. 4 is a cross-sectional view of the display panel DP according to an embodiment of the inventive concept. FIG. 4 exemplarily illustrates a cross section of the display panel DP corresponding to any one pixel PX illustrated in FIG. 3.

Referring to FIG. 4, the pixel PX, e.g., see FIG. 3, may include a transistor TR and a light-emitting element ED. The transistor TR and the light-emitting element ED may be disposed on the base substrate SUB. Although one transistor TR is illustrated in FIG. 4, the pixel PX, e.g., see FIG. 3, may substantially include a plurality of transistors and at least one capacitor for driving the light-emitting element ED.

The circuit element layer CL may be disposed on the base substrate SUB. The circuit element layer CL may include a shield electrode BML, the transistor TR, connection electrodes CNE, and a plurality of insulating layers BFL and INS1 to INS6. The plurality of insulating layers BFL and INS1 to INS6 may include a buffer layer BFL and first to sixth insulating layers INS1 to INS6. However, the stacking structure of the circuit element layer CL illustrated in FIG. 4 is exemplary, and the stacking structure of the circuit element layer CL may be changed according to the structure of the pixel PX, e.g., see FIG. 3, and the process of the circuit element layer CL.

The shield electrode BML may be disposed on the base substrate SUB. The shield electrode BML may overlap the transistor TR. The shield electrode BML may protect the transistor TR by blocking light incident from the lower portion of the display panel DP to the transistor TR. The shield electrode BML may contain a conductive material. In an embodiment of the inventive concept, the shield electrode BML may be connected to the power line PL, e.g., see FIG. 3, so as to be able to receive a voltage. When a voltage is applied to the shield electrode BML, a threshold voltage of the transistor TR disposed on the shield electrode BML may be maintained. Without being limited thereto, the shield electrode BML may be a floating electrode. In an embodiment of the inventive concept, the shield electrode BML may be omitted.

The buffer layer BFL may be disposed on the base substrate SUB so as to be able to cover the shield electrode BML. The buffer layer BFL may include an inorganic layer. The buffer layer BFL may improve bonding strength between the base substrate SUB and a semiconductor pattern or a conductive pattern disposed on the buffer layer BFL.

The transistor TR may include a source S, a channel C, a drain D, and a gate G. The source S, the channel C, and the drain D of the transistor TR may be formed from a semiconductor pattern. The semiconductor pattern of the transistor TR may contain polysilicon, amorphous silicon, or metal oxide, but the embodiment of the inventive concept is not limited to any one material as long as the material has semiconductor properties.

The semiconductor pattern may include a plurality of regions classified according to conductivity. In the semiconductor pattern, a region doped with a dopant or a region in which metal oxide is reduced may have high conductivity and substantially serve as a source electrode and a drain electrode of the transistor TR. A region having high conductivity in the semiconductor pattern may correspond to the source S and the drain D of the transistor TR. A region having low conductivity due to being non-doped, or being doped at a low concentration, or because metal oxide is not reduced may correspond to the channel C (or active region) of the transistor TR.

The first insulating layer INS1 may cover the semiconductor pattern of the transistor TR and be disposed on the buffer layer BFL. The gate G of the transistor TR may be disposed on the first insulating layer INS1. The gate G may overlap the channel C of the transistor TR. In an embodiment of the inventive concept, the gate G may function as a mask in a process of doping the semiconductor pattern of the transistor TR.

The second insulating layer INS2 may cover the gate G and be disposed on the first insulating layer INS1. The third insulating layer INS3 may be disposed on the second insulating layer INS2.

The connection electrodes CNE may include a first connection electrode CNE1 and a second connection electrode CNE2 for electrically connecting the transistor TR and the light-emitting element ED to each other. However, the embodiment of the connection electrodes CNE connecting the transistor TR and the light-emitting element ED to each other is not limited thereto, and one of the first and second connection electrodes CNE1 and CNE2 may be omitted, or an additional connection electrode may be further included.

The first connection electrode CNE1 may be disposed on the third insulating layer INS3. The first connection electrode CNE1 may be connected to the drain D through a first contact hole CH1 passing through the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 passing through the fourth and fifth insulating layers INS4 and INS5. The sixth insulating layer INS6 may cover the second connection electrode CNE2 and be disposed on the fifth insulating layer INS5.

Each of the first to sixth insulating layers INS1 to INS6 may include an inorganic layer or an organic layer. For example, the inorganic layer may contain at least one of aluminum oxide, titanium oxide, silicon oxide, silicon oxynitride, zirconium oxide, or hafnium oxide. The organic layer may contain at least any one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin.

The display element layer OL may include a pixel defining film PDL and the light-emitting element ED. The light-emitting element ED may include a first electrode EL1, a hole transport region HTR, an electron transport region ETR, a light emitting layer EML, and a second electrode EL2.

The first electrode EL1 may be disposed on the sixth insulating layer INS6. The first electrode EL1 may be connected to the second connection electrode CNE2 through a third contact hole CH3 passing through the sixth insulating layer INS6. The first electrode EL1 may be electrically connected to the drain D of the transistor TR through the first and second connection electrodes CNE1 and CNE2.

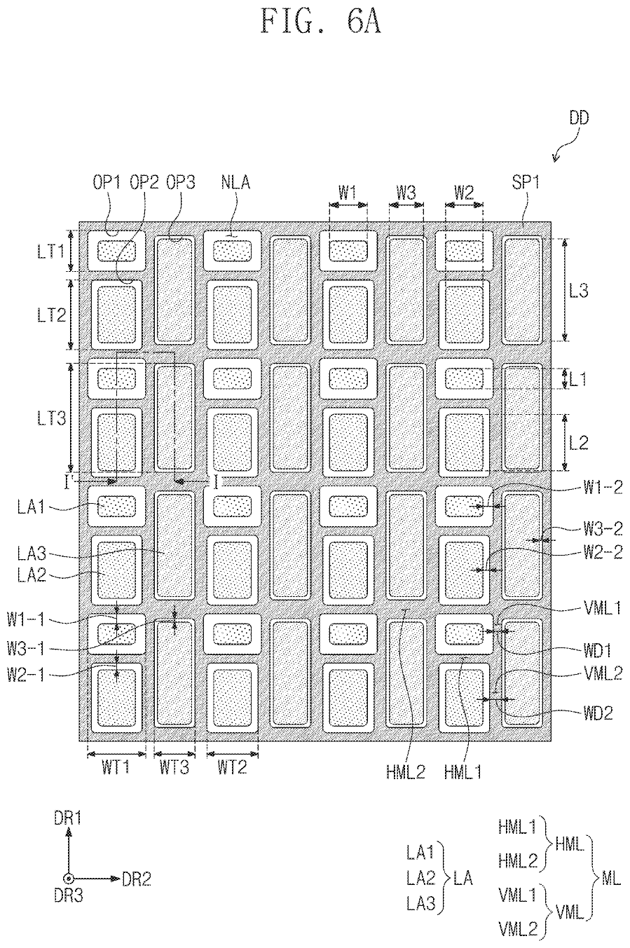

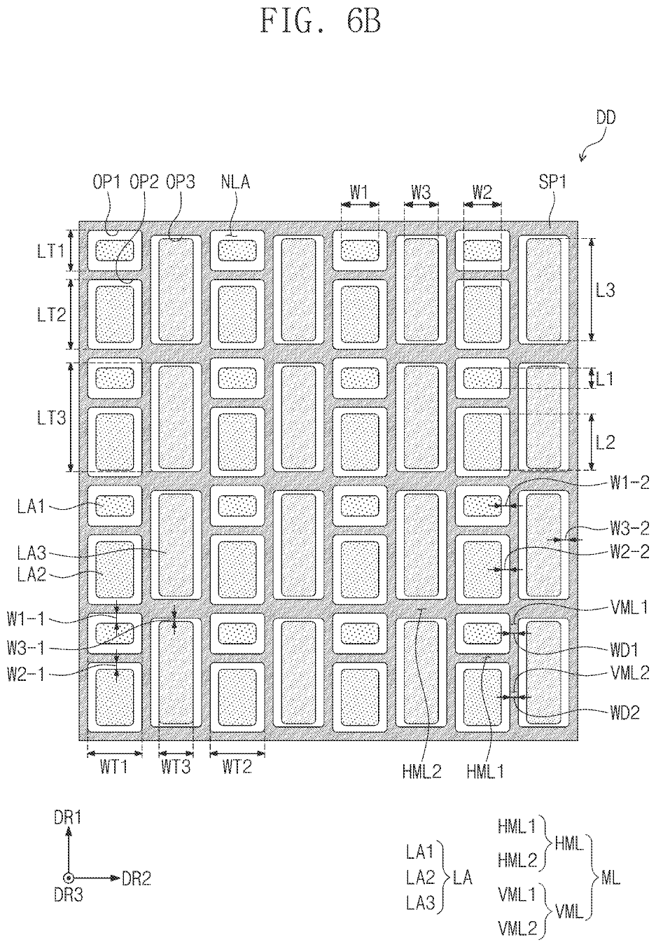

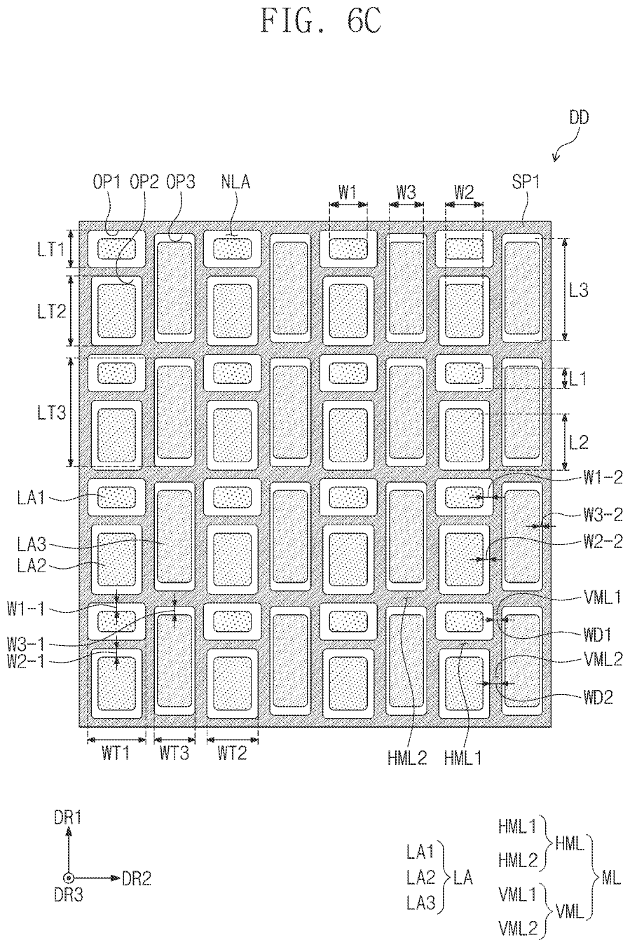

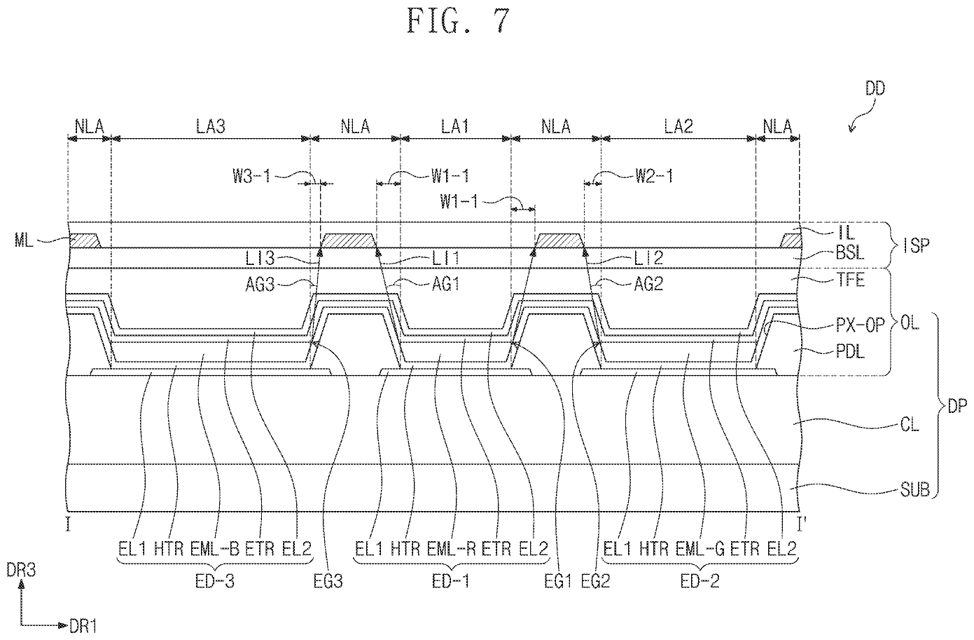

The pixel defining film PDL may be disposed on the sixth insulating layer INS6. A light-emitting opening PX-OP exposing a portion of the first electrode EL1 may be defined in the pixel defining film PDL. The portion of the first electrode EL1 exposed by the light-emitting opening PX-OP may be defined as an emission region LA. The emission region LA may correspond to one of first to third emission regions LA1, LA2, and LA3, e.g., see FIG. 6A, to be described later.

A region in which the pixel defining film PDL is disposed may correspond to a non-emission region NLA. The non-emission region NLA may surround the emission region LA in the display region DA.

The hole transport region HTR may be disposed on the first electrode EL1 and the pixel defining film PDL. The hole transport region HTR may be provided as a common layer overlapping the emission region LA and the non-emission region NLA. The hole transport region HTR may include at least any one of a hole transport layer, a hole injection layer, or an electron blocking layer.

The light emitting layer EML may be disposed on the hole transport region HTR. The light emitting layer EML may be disposed in a region corresponding to the light-emitting opening PX-OP. However, the embodiment of the inventive concept is not necessarily limited thereto, and the light emitting layer EML may be provided as a common layer. The light emitting layer EML may contain an organic material and/or an inorganic material. The light emitting layer EML may emit light of any one of red, green, and blue colors.

The electron transport region ETR may be disposed on the light emitting layer EML. The electron transport region ETR may be provided as a common layer overlapping the emission region LA and the non-emission region NLA. The electron transport region ETR may include at least any one of an electron transport layer, an electron injection layer, or a hole blocking layer.

The second electrode EL2 may be disposed on the electron transport region ETR. The second electrode EL2 may be provided as a common layer overlapping the emission region LA and the non-emission region NLA. The second electrode EL2 may be disposed in common in the pixels PX, e.g., see FIG. 3, so as to be able to apply a voltage to the pixels PX, e.g., see FIG. 3.

The thin film encapsulation layer TFE may be disposed on the second electrode EL2 and cover the light-emitting element ED. The thin film encapsulation layer TFE may include a plurality of thin films. For example, the thin film encapsulation layer TFE may include inorganic layers disposed on the second electrode EL2 and an organic layer disposed between the inorganic layers. The inorganic layer of the thin film encapsulation layer TFE may protect the light-emitting element ED from moisture/oxygen, and the organic layer may protect the light-emitting element ED from foreign substances such as dust particles. However, the embodiment of the thin film encapsulation layer TFE is not necessarily limited thereto.

A first voltage may be applied to the first electrode EL1 through the transistor TR, and a second voltage having a lower level than the first voltage may be applied to the second electrode EL2. Holes and electrons injected into the light emitting layer EML may be combined with each other to form excitons, and the light-emitting element ED may emit light while the excitons transition to a ground state.

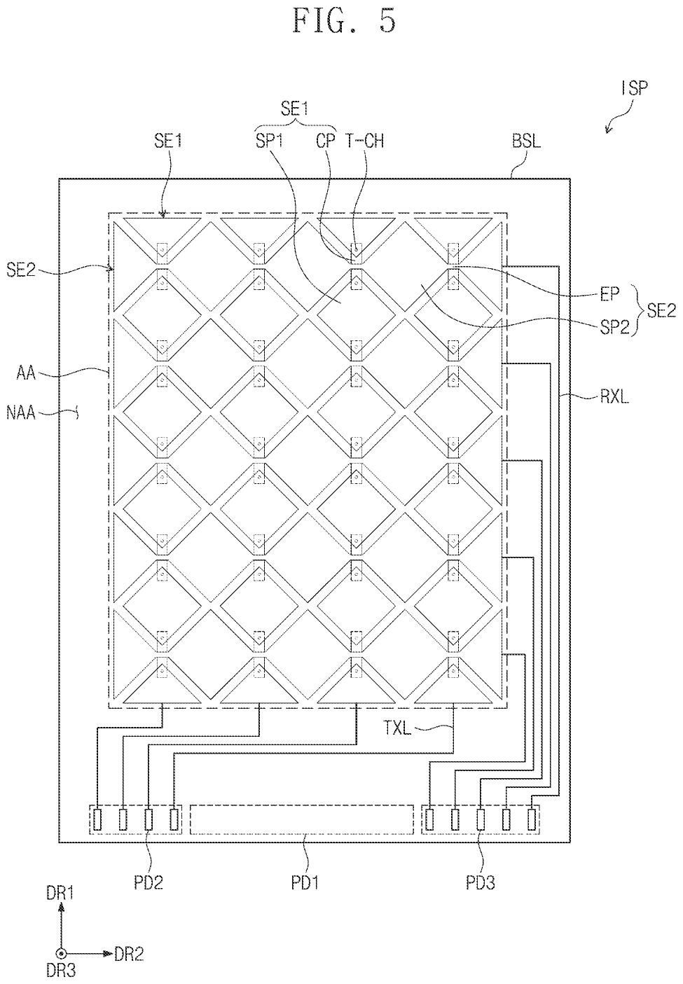

FIG. 5 is a plan view of an input sensing layer ISP according to an embodiment of the inventive concept.

The input sensing layer ISP may be disposed on the display panel DP, e.g., see FIG. 3, described above. The input sensing layer ISP may be formed directly on the base surface provided by the display panel DP, e.g., see FIG. 3. In an embodiment of the inventive concept, the input sense layer ISP may be driven by a mutual-cap method. Without being limited thereto, however, the input sensing layer ISP may be driven by a self-cap method.

The input sensing layer ISP may include a base layer BSL, first sensing electrodes SE1, second sensing electrodes SE2, first sensing lines TXL, second sensing lines RXL, second pads PD2, and third pads PD3.

The base layer BSL may provide a base surface on which the electrodes and lines of the input sensing layer ISP are disposed. In an embodiment of the inventive concept, the base layer BSL may be disposed directly on the thin film encapsulation layer TFE, e.g., see FIG. 4, of the display panel DP, e.g., see FIG. 4. Without being limited thereto, however, the base layer BSL may be omitted, and the electrodes and lines of the input sensing layer ISP may be disposed directly on the thin film encapsulation layer TFE, e.g., see FIG. 4.

The base layer BSL may include an active region AA and a peripheral region NAA. The active region AA may overlap the display region DA, e.g., see FIG. 3, and the peripheral region NAA may overlap the non-display region NDA, e.g., see FIG. 3.

Each of the first sensing electrodes SE1 may extend in the first direction DR1, and the first sensing electrodes SE1 may be disposed in the second direction DR2. Although FIG. 5 illustrates four first sensing electrodes SE1 as an example, the number of the first sensing electrodes SE1 included in the input sensing layer ISP is not limited thereto. Each of the first sensing electrodes SE1 may include first sensing units SP1 and connection patterns CP connecting the first sensing units SP1 to each other.

The first sensing units SP1 may be disposed along the first direction DR1. Each of the connection patterns CP may be disposed between adjacent first sensing units SP1 in the first direction DR1 to electrically connect the first sensing units SP1 to each other. Each of the connection patterns CP may extend in the first direction DR1. The connection patterns CP may overlap the first sensing units SP1 adjacent thereto in the first direction DR1 on a plane. However, the shape of the connection patterns CP is not limited to any one shape as long as it can electrically connect adjacent first sensing units SP1 to each other.

The connection patterns CP may be disposed on a layer different from that of the first sensing units SP1. The connection patterns CP may be connected to corresponding first sensing units SP1 through contact holes T-CH. The contact holes T-CH may be formed by passing through an insulating layer disposed between the connection patterns CP and the first sensing units SP1.

Each of the second sensing electrodes SE2 may extend in the second direction DR2, and the second sensing electrodes SE2 may be disposed in the first direction DR1. Although FIG. 5 illustrates five second sensing electrodes SE2 as an example, the number of the second sensing electrodes SE2 included in the input sensing layer ISP is not limited thereto. Each of the second sensing electrodes SE2 may include second sensing units SP2 and extension patterns EP connecting the second sensing units SP2 to each other.

The second sensing units SP2 may be disposed along the second direction DR2. Each of the extension patterns EP may be disposed between adjacent second sensing units SP2 in the second direction DR2 to electrically connect the second sensing units SP2 to each other.

Each of the extension patterns EP may extend in the second direction DR2. The extension patterns EP may be insulated from and cross the connection patterns CP on a plane. The extension patterns EP may extend from corresponding second sensing units SP2. That is, the connection patterns EP and the second sensing units SP2 may be disposed on the same layer as each other so as to have an integral shape with each other.

The first sensing electrodes SE1 and the second sensing electrodes SE2 may be electrically insulated from and cross each other on a plane. The input sensing layer ISP may sense an external input through a change in capacitance between the first sensing electrodes SE1 and the second sensing electrodes SE2. The first sensing electrodes SE1 and the second sensing electrodes SE2 may be disposed in the active region AA overlapping the display region DA, e.g., see FIG. 3. Accordingly, the display device DD, e.g., see FIG. 1, can sense an external input applied to the display region DA, e.g., see FIG. 1, while displaying an image through the display region DA, e.g., see FIG. 1.

The first sensing lines TXL may be disposed on the peripheral region NAA and electrically connected to the first sensing electrodes SE1, respectively. For example, the first sensing lines TXL may be electrically connected to the lower ends of the first sensing electrodes SE1, respectively. The first sensing lines TXL may be disposed to be adjacent to the lower portion of the peripheral region NAA on a plane. The first sensing lines TXL may respectively extend from the lower ends of the first sensing electrodes SE1 toward the second pads PD2.

The first sensing lines TXL may be electrically connected to the second pads PD2, respectively. The first sensing lines TXL may be disposed on a layer different from that of the second pads PD2 and connected to the second pads PD2 through a contact hole, or may have an integral shape with the second pads PD2.

The second sensing lines RXL may be disposed on the peripheral region NAA and electrically connected to the second sensing electrodes SE2, respectively. For example, the second sensing lines RXL may be electrically connected to the right ends of the second sensing electrodes SE2, respectively. The second sensing lines RXL may be disposed to be adjacent to the right side of the peripheral region NAA on a plane. However, the embodiment of the inventive concept is not limited thereto, and the second sensing lines RXL may be disposed to be adjacent to the left side of the peripheral region NAA, or the second sensing lines RXL may be dividedly disposed on the left and right sides of the peripheral region NAA. The second sensing lines RXL may respectively extend from the right ends of the second sensing electrodes SE2 toward the third pads PD3.

The second sensing lines RXL may be electrically connected to the third pads PD3, respectively. The second sense lines RXL may be disposed on a layer different from that of the third pads PD3 and connected through a contact hole, or may have an integral shape with the third pads PD3.

A touch controller for controlling the input sensing layer ISP may be electrically connected to the second pads PD2 and the third pads PD3 through a circuit board. The second pads PD2 and the third pads PD3 may be disposed along the second direction DR2. The second pads PD2 may be disposed to be adjacent to the lower left end of the peripheral region NAA on a plane, and the third pads PD3 may be disposed to be adjacent to the lower right end of the peripheral region NAA on a plane.

The first pads PD1 of the display panel DP, e.g., see FIG. 3, may be disposed between the second pads PD2 and the third pads PD3. The second pads PD2 and the third pads PD3 may be disposed on substantially the same layer as the first pads PD1. Without being limited thereto, however, the second pads PD2 and the third pads PD3 may be disposed on a layer different from that of the first pads PD1. The configuration of the pads PD1, PD2, and PD3 illustrated in FIGS. 3 and 5 is exemplary, and the embodiment of the inventive concept is not limited thereto.

FIGS. 6A to 6C are enlarged plan views of a portion of the display device DD according to an embodiment of the inventive concept. FIGS. 6A to 6C are enlarged plan views of a portion in which the first sensing unit SP1 is disposed on the display panel DP according to an embodiment of the inventive concept. Each of FIGS. 6A to 6C exemplarily illustrates the first sensing unit SP1 of the input sensing layer ISP, e.g., see FIG. 5. A description of the first sensing unit SP1 to be described later may also be applied to the second sensing unit SP2, e.g., see FIG. 5.

Referring to FIG. 6A, the display device DD according to an embodiment of the inventive concept may include first to third emission regions LA1 to LA3 and a non-emission region NLA. The display panel DP, e.g., see FIG. 7, according to an embodiment of the inventive concept may include emission regions LA1, LA2, and LA3.

The display panel DP, e.g., see FIG. 4, may include light-emitting elements ED-1, ED-2, and ED-3, e.g., see FIG. 7, and the emission regions LA1, LA2, and LA3 may respectively correspond to regions in which the light-emitting elements ED-1, ED-2, and ED-3, e.g., see FIG. 7, are disposed. The emission regions LA1, LA2, and LA3 may include first to third emission regions LA1, LA2, and LA3 classified according to the colors of light emitted therefrom. The first to third emission regions LA1, LA2, and LA3 may be respectively defined as regions in which the first to third light-emitting elements ED-1, ED-2, and ED-3, e.g., see FIG. 7, are disposed. When viewed on a plane, the first to third emission regions LA1, LA2, and LA3 may be portions from which light is emitted, and the non-emission region NLA may be a portion from which light is not emitted. The non-emission region NLA may be disposed between the first to third emission regions LA1, LA2, and LA3.

The first to third emission regions LA1, LA2, and LA3 may emit light of different colors. For example, the first emission region LA1 may emit red light, the second emission region LA2 may emit green light, and the third emission region LA3 may emit blue light. However, the colors of light emitted through the first to third emission regions LA1, LA2, and LA3 are not limited thereto.

Each of the first to third emission regions LA1, LA2, and LA3 may be provided in plurality, and the plurality of first to third emission regions LA1, LA2, and LA3 may be disposed in a predetermined configuration on a plane. The first emission region LA1, the second emission region LA2, and the third emission region LA3 may be defined as one pixel unit. The pixel unit including the first emission region LA1, the second emission region LA2, and the third emission region LA3 may be provided in plurality, and the plurality of pixel units may be disposed along the first and second directions DR1 and DR2.

The first emission regions LA1, the second emission regions LA2, and the third emission regions LA3 may be disposed along the first and second directions DR1 and DR2 on a plane. In the first direction DR1, the first emission regions LA1 and the second emission regions LA2 may be alternately disposed with each other. The third emission regions LA3 may be disposed along the first direction DR1 and may not overlap the first emission regions LA1 or the second emission regions LA2 in the first direction DR1.

Each of the third emission regions LA3 may overlap at least a portion of the first emission region LA1 and the second emission region LA2 in the second direction DR2. The first emission regions LA1 and the third emission regions LA3 may be alternately disposed with each other in the second direction DR2, and the second emission regions LA2 and the third emission regions LA3 may be alternately disposed with each other in the second direction DR2. However, the configuration of the first to third emission regions LA1, LA2, and LA3 illustrated in FIG. 6A is exemplary, and the embodiment of the inventive concept is not limited thereto.

The first emission regions LA1 and the second emission regions LA2 disposed along the first direction DR1 may be defined as a first light-emitting column, and the third emission regions LA3 disposed along the first direction DR1 may be defined as a second light-emitting column. Each of the first light-emitting column and the second light-emitting column may be provided in plurality, and the first light-emitting columns and the second light-emitting columns may be alternately disposed along the second direction DR2.

The first to third emission regions LA1, LA2, and LA3 may have various shapes on a plane. For example, the first to third emission regions LA1, LA2, and LA3 may substantially have a polygonal shape such as a tetragon or an octagon, a circular shape, or an elliptical shape. The shape of each of the first to third emission regions LA1, LA2, and LA3 may correspond to the shape of the light-emitting opening PX-OP, e.g., see FIG. 4, of the pixel defining film PDL, e.g., see FIG. 4.

The first to third emission regions LA1, LA2, and LA3 may have a predetermined area on a plane. For example, the first to third emission regions LA1, LA2, and LA3 may have different areas on a plane. On a plane, the area of the first emission region LA1 may be less than the area of the second emission region LA2, and the area of the second emission region LA2 may be less than the area of the third emission region LA3.

In an embodiment of the inventive concept, the first emission region LA1 may have a first length L1 in the first direction DR1. The second emission region LA2 may have a second length L2 in the first direction DR1. The third emission region LA3 may have a third length L3 in the first direction DR1. The first length L1 may be less than the second length L2, and the second length L2 may be less than the third length L3.

In an embodiment of the inventive concept, the first emission region LA1 may have a first width W1 in the second direction DR2. The second emission region LA2 may have a second width W2 in the second direction DR2. The third emission region LA3 may have a third width W3 in the second direction DR2. The first width W1 and the second width W2 may be the same as each other, and the third width W3 may be less than each of the first width W1 and the second width W2. However, this is only exemplary, and the embodiment of the inventive concept is not limited thereto. For example, the first width W1 may be less than the second width W2, and the second width W2 may be less than the third width W3.

Meanwhile, the areas of the first to third emission regions LA1, LA2, and LA3, the lengths thereof in the first direction DR1, and the widths thereof in the second direction DR2 may be designed in various ways according to the light output color, the light output efficiency, the resolution, and the size of the display device DD, e.g., see FIG. 1.

In an embodiment of the inventive concept, a plurality of openings OP1 to OP3 may be defined in the first sensing unit SP1. The openings OP1 to OP3 may be defined in portions corresponding to the emission regions LA1 to LA3. The first opening OP1 may be defined to correspond to the first emission region LA1, the second opening OP2 may be defined to correspond to the second emission region LA2, and the third opening OP3 may be defined to correspond to the third emission region LA3. Meanwhile, the area of each of the first to third emission regions LA1 to LA3 may be less than the area of each of the first to third openings OP1 to OP3. The first sensing unit SP1 may expose the emission regions LA1 to LA3 through the openings OP1 to OP3.

Meanwhile, when the ratio of the area of each of the emission regions LA1 to LA3 to the area of each of the openings OP1 to OP3 is small, the areas of the emission regions LA1 to LA3 covered by the sensing unit SP1 may be small. When the ratio of the area of each of the emission regions LA1 to LA3 to the area of each of the openings OP1 to OP3 is large, the covered areas of the emission regions LA1 to LA3 may be large. In this specification, the covered area of the emission region means the area of the emission region covered by the sensing unit at a specific viewing angle. In this specification, the viewing angle represents an angle between measurement points facing the display device DD, e.g., see FIG. 1, on a reference axis parallel to the third direction DR3.

In an embodiment of the inventive concept, the ratio of the area of the first emission region LA1 to the area of the first opening OP1 may be less than the ratio of the area of the second emission region LA2 to the area of the second opening OP2. The ratio of the area of the second emission region LA2 to the area of the second opening OP2 may be less than the ratio of the area of the third emission region LA3 to the area of the third opening OP3. That is, the covered area of the first emission region LA1 may be less than the covered area of the second emission region LA2, and the covered area of the second emission region LA2 may be less than the covered area of the third emission region LA3.

As illustrated in FIG. 6A, the area of the first emission region LA1 may be less than the area of the second emission region LA2, and the area of the second emission region LA2 may be less than the area of the third emission region LA3. In the display device DD, e.g., see FIG. 1, according to an embodiment of the inventive concept, by adjusting a emission region having a large area so as to have a large covered area and adjusting a emission region having a small area so as to have a small covered area, it is possible to adjust the covered rates of the emission regions so that they may be substantially the same as each other. In this specification, the covered rate means a ratio of the covered area of an emission region to the area of the emission region. That is, the greater the covered rate is, the greater the covered area of an emission region is, and therefore the reduction of luminance is great, while the less the covered rate is, the less the covered area of the emission region is, and therefore the reduction of luminance is small. Accordingly, in this specification, a change in the covered rate of an emission region according to a change in the viewing angle may correspond to a change in luminance of the emission region according to the change in the viewing angle.

Meanwhile, when the covered rates of the emission regions are different from each other, a difference in luminance between the emission regions may occur, thus affecting the color of the image IM, e.g., see FIG. 1, displayed on the display device DD, e.g., see FIG. 1. In the display device DD according to an embodiment of the inventive concept, the covered rate of the first emission region LA1, the covered rate of the second emission region LA2, and the covered rate of the third emission region LA3 may be substantially the same as each other. In the display device DD, e.g., see FIG. 1, according to an embodiment of the inventive concept, by adjusting, to the same level, changes in the covered rates of the first to third emission regions LA1 to LA3 according to a change in the viewing angle, it is possible to minimize a difference in luminance between the emission regions according to the change in the viewing angle. As a result, the display device DD, e.g., see FIG. 1, according to an embodiment of the inventive concept may minimize a change in color of the image IM, e.g., FIG. 1, displayed on the display device DD, e.g., see FIG. 1, according to the change in the viewing angle, thereby exhibiting excellent display quality.

In an embodiment of the inventive concept, a first opening length LT1 of the first opening OP1 in the first direction DR1 may be less than a second opening length LT2 of the second opening OP2 in the first direction DR1. The second opening length LT2 of the second opening OP2 in the first direction DR1 may be less than a third opening length LT3 of the third opening OP3 in the first direction DR1. An absolute value of a difference between the first opening length LT1 and the first length L1 may be greater than an absolute value of a difference between the second opening length LT2 and the second length L2. An absolute value of a difference between the second opening length LT2 and the second length L2 may be greater than an absolute value of a difference between the third opening length LT3 and the third length L3.

In an embodiment of the inventive concept, the first opening OP1 may have a first opening width WT1 in the second direction DR2. The second opening OP2 may have a second opening width WT2 in the second direction DR2. The third opening OP3 may have a third opening width WT3 in the second direction DR2. An absolute value of a difference between the first opening width WT1 and the first width W1 may be greater than an absolute value of a difference between the second opening width WT2 and the second width W2. An absolute value of a difference between the second opening width WT2 and the second width W2 may be greater than an absolute value of a difference between the third opening width WT3 and the third width W3.

By adjusting the absolute value of the difference between the first opening length LT1 and the first length L1, the absolute value of the difference between the second opening length LT2 and the second length L2, and the absolute value of the difference between the third opening length LT3 and the third length L3, it is possible to adjust the covered area and covered rate of each of the emission regions LA1, LA2, and LA3 when viewed in the first direction DR1. Specifically, in the display device DD, e.g., see FIG. 1, according to an embodiment of the inventive concept, by adjusting the absolute value of the difference between the first opening length LT1 and the first length L1, the absolute value of the difference between the second opening length LT2 and the second length L2, and the absolute value of the difference between the third opening length LT3 and the third length L3 so that the absolute values sequentially increase, it is possible to adjust the covered rates of the first to third emission regions LA1 to LA3 to the same level when viewed in the first direction DR1. Accordingly, the display device DD, e.g., see FIG. 1, according to an embodiment of the inventive concept may minimize a difference in luminance between the emission regions according to a change in the viewing angle in the first direction DR1, thereby exhibiting excellent display quality.

By adjusting the absolute value of the difference between the first opening width WT1 and the first width W1, the absolute value of the difference between the second opening width WT2 and the second width W2, and the absolute value of the difference between the third opening width WT3 and the third width W3, it is possible to adjust the covered area and covered rate of each of the emission regions LA1, LA2, and LA3 when viewed in the second direction DR2. Specifically, in the display device DD, e.g., see FIG. 1, according to an embodiment of the inventive concept, by adjusting the absolute value of the difference between the first opening width WT1 and the first width W1, the absolute value of the difference between the second opening width WT2 and the second width W2, and the absolute value of the difference between the third opening width WT3 and the third width W3 so that the absolute values sequentially increase, it is possible to adjust the covered rates of the first to third emission regions LA1 to LA3 to the same level when viewed in the second direction DR2. Accordingly, the display device DD, e.g., see FIG. 1, according to an embodiment of the inventive concept may minimize a difference in luminance between emission regions according to a change in the viewing angle in the second direction DR2.

Meanwhile, FIG. 6A illustrates that the absolute value of the difference between the first opening length LT1 and the first length L1, the absolute value of the difference between the second opening length LT2 and the second length L2, the absolute value of the difference between the third opening length LT3 and the third length L3, the absolute value of the difference between the first opening width WT1 and the first width W1, the absolute value of the difference between the second opening width WT2 and the second width W2, and the absolute value of the difference between the third opening width WT3 and the third width W3 are all different from each other, but the embodiment of the inventive concept is not limited thereto.

For example, as illustrated in FIG. 6B, the absolute value of the difference between the first opening length LT1 and the first length L1, the absolute value of the difference between the second opening length LT2 and the second length L2, and the absolute value of the difference between the third opening length LT3 and the third length L3 may be substantially the same as each other. In addition, as illustrated in FIG. 6C, the absolute value of the difference between the first opening width WT1 and the first width W1, the absolute value of the difference between the second opening width WT2 and the second width W2, and the absolute value of the difference between the third opening width WT3 and the third width W3 may be substantially the same as each other.

In an embodiment of the inventive concept, a sensing unit ML may include a vertical sensing part VML extending in the first direction DR1 and a horizontal sensing part HML extending in the second direction DR2. Each of the openings OP1 to OP3 may be defined by being surrounded by the vertical sensing part VML and the horizontal sensing part HML.

In an embodiment of the inventive concept, the vertical sensing part VML may include a first vertical sensing part VML1 and a second vertical sensing part VML2. The first vertical sensing part VML1 may be disposed between the first emission region LA1 and the third emission region LA3. The first vertical sensing part VML1 may be disposed between the first opening OP1 and the third opening OP3. The second vertical sensing part VML2 may be disposed between the second emission region LA2 and the third emission region LA3. The second vertical sensing part VML2 may be disposed between the second opening OP2 and the third opening OP3.

In an embodiment of the inventive concept, the horizontal sensing part HML may include a first horizontal sensing part HML1 and a second horizontal sensing part HML2. The first horizontal sensing part HML1 may be disposed between the first emission region LA1 and the second emission region LA2. The first horizontal sensing part HML1 may be disposed between the first opening OP1 and the second opening OP2. The second horizontal sensing part HML2 may be disposed between adjacent third emission regions LA3. The second horizontal sensing part HML2 may be disposed between adjacent third openings OP3.

The first horizontal sensing part HML1 may be closer to the second emission region LA2 than to the first emission region LA1. A first vertical distance W1-1 between the first horizontal sensing part HML1 and the first emission region LA1 may be greater than a second vertical distance W2-1 between the first horizontal sensing part HML1 and the second emission region LA2. Accordingly, in the first direction DR1, the covered area of the first emission region LA1 may be less than the covered area of the second emission region LA2, and the covered rates of the first emission region LA1 and the second emission region LA2 may be substantially the same as each other. A third vertical distance W3-1 between the second horizontal sensing part HML2 and the third emission region LA3 may be less than each of the first vertical distance W1-1 and the second vertical distance W2-1. Accordingly, the covered area of the third emission region LA3 may be greater than the covered area of the first emission region LA1 and the covered area of the second emission region LA2. Accordingly, in the first direction DR1, the covered rate of the first emission region LA1, the covered rate of the second emission region LA2, and the covered rate of the third emission region LA3 may be substantially the same as each other. As a result, the display device DD, e.g., see FIG. 1, according to an embodiment of the inventive concept may exhibit excellent display quality.

The first vertical sensing part VML1 may be closer to the third emission region LA3 than the first emission region LA1. A first horizontal distance W1-2 between the first vertical sensing part VML1 and the first emission region LA1 may be greater than a third horizontal distance W3-2 between the first vertical sensing part VML1 and the third emission region LA3. Accordingly, in the second direction DR2, the covered area of the first emission region LA1 may be less than the covered area of the third emission region LA3, and the covered rates of the first emission region LA1 and the third emission region LA3 may be substantially the same as each other.

The second vertical sensing part VML2 may be closer to the third emission region LA3 than the second emission region LA2. A second horizontal distance W2-2 between the second vertical sensing part VML2 and the second emission region LA2 may be greater than the third horizontal distance W3-2 between the second vertical sensing part VML2 and the third emission region LA3. Accordingly, in the second direction DR2, the covered area of the second emission region LA2 may be less than the covered area of the third emission region LA3, and the covered rates of the second emission region LA2 and the third emission region LA3 may be substantially the same as each other. As a result, in the second direction DR2, the covered rate of the first emission region LA1, the covered rate of the second emission region LA2, and the covered rate of the third emission region LA3 may be substantially the same as each other, and therefore, the display device DD, e.g., see FIG. 1, according to an embodiment of the inventive concept may exhibit excellent display quality.

Based on the second direction DR2, a width WD1 of the first vertical sensing part VML1 may be the same as a width WD2 of the second vertical sensing part VML2. However, this is only exemplary, and the embodiment of the inventive concept is not limited thereto. For example, based on the second direction DR2, the width WD1 of the first vertical sensing part VML1 and the width WD2 of the second vertical sensing part VML2 may be different from each other. Specifically, based on the second direction DR2, the width WD2 of the second vertical sensing part VML2 may be less than the width WD1 of the first vertical sensing part VML1. As a result, by adjusting the covered area of the second emission region LA2 so that it can be greater than the covered area of the first emission region LA1, it is possible to adjust the covered rate of the second emission region LA2 so that it can be substantially the same as the covered rate of the first emission region LA1.

FIG. 7 is a cross-sectional view of the display device DD according to an embodiment of the inventive concept. FIG. 7 is a cross-sectional view of a portion corresponding to line I-I′ illustrated in FIG. 6A.

Referring to FIG. 7, the display panel DP according to an embodiment of the inventive concept may include the first to third light-emitting elements ED-1, ED-2, and ED-3. The first to third light-emitting elements ED-1, ED-2, and ED-3 may be respectively disposed to correspond to the first to third emission regions LA1, LA2, and LA3.

In an embodiment of the inventive concept, each of the first to third light-emitting elements ED-1, ED-2, and ED-3 may include a first electrode EL1, a hole transport region HTR disposed on the first electrode EL1, a light emitting layer EML-R, EML-G, or EML-B disposed on the hole transport region HTR, an electron transport region ETR disposed on the light emitting layer EML-R, EML-G, or EML-B, and a second electrode EL2 disposed on the electron transport region ETR. Meanwhile, the same contents as described in FIG. 4 may be applied to the first electrode EL1, the hole transport region HTR, the electron transport region ETR, and the second electrode EL2.

In an embodiment of the inventive concept, the input sensing layer ISP may include a base layer BSL, a sensing insulating layer IL, and a sensing unit ML. In an embodiment of the inventive concept, the base layer BSL may be disposed on the thin film encapsulation layer TFE. The base layer BSL may include at least one inorganic insulating layer. The base layer BSL may come in contact with the thin film encapsulation layer TFE. Without being limited thereto, however, in an embodiment of the inventive concept, the base layer BSL may be omitted.

The sensing unit ML may be disposed on the base layer BSL. The sensing unit ML may be disposed directly on the base layer BSL. However, this is only exemplary, and the embodiment of the inventive concept is not limited thereto, and an insulating layer may be disposed between the sensing unit ML and the base layer BSL. The sensing insulating layer IL may be disposed on the base layer BSL and cover the sensing unit ML. The sensing insulating layer IL may include an inorganic insulating layer or an organic insulating layer.

A distance W1-1 from an edge portion EG1 of a first light emitting layer EML-R to the sensing unit ML adjacent to the edge portion EG1 of the first light emitting layer EML-R may be greater than a distance W2-1 from an edge portion EG2 of a second light emitting layer EML-G to the sensing unit ML adjacent to the edge portion EG2 of the second light emitting layer EML-G. The distance W2-1 from the edge portion EG2 of the second light emitting layer EML-G to the sensing unit ML adjacent to the edge portion EG2 of the second light emitting layer EML-G may be greater than a distance W3-1 from an edge portion EG3 of a third light emitting layer EML-B to the sensing unit ML adjacent to the edge portion EG3 of the third light emitting layer EML-B. Accordingly, an angle, at which the sensing unit ML starts to cover the light emitting layer EML-R, EML-G, or EML-B, may vary.

A first angle AG1 between the third direction axis DR3 and a first imaginary inclined line LI1 extending from the edge portion EG1 of the first light emitting layer EML-R toward the sensing unit ML adjacent to the edge portion EG1 of the first light emitting layer EML-R may be greater than a second angle AG2 between the third direction axis DR3 and a second imaginary inclined line LI2 extending from the edge portion EG2 of the second light emitting layer EML-G toward the sensing unit ML adjacent to the edge portion EG2 of the second light emitting layer EML-G. The second angle AG2 between the third direction axis DR3 and the second imaginary inclined line LI2 extending from the edge portion EG2 of the second light emitting layer EML-G toward the sensing unit ML adjacent to the edge portion EG2 of the second light emitting layer EML-G may be greater than a third angle AG3 between the third direction axis DR3 and a third imaginary inclined line LI3 extending from the edge portion EG3 of the third light emitting layer EML-B toward the sensing unit ML adjacent to the edge portion EG3 of the third light emitting layer EML-B.

Each of the first angle AG1, the second angle AG2, and the third angle AG3 is an angle at which light is started to be blocked. It means that the covered area of the emission region is greater when an angle at which light is started to be blocked is less. It means that the covered area of the emission region is less when an angle at which light is started to be blocked is greater. That is, as the first angle AG1, the second angle AG2, and the third angle AG3 are progressively less in the order named, the covered areas of the first emission region LA1, the second emission region LA2, and the third emission region LA3 may be progressively greater in the order named. Accordingly, it is possible to adjust the covered rates of the first emission region LA1, the second emission region LA2, and the third emission region LA3, which have different areas, so that the covered rates thereof are substantially the same as each other.

That is, in the display device DD according to an embodiment of the inventive concept, by making adjustments so that an angle at which light is started to be blocked is less when the area of the emission region is greater and an angle at which light is started to be blocked is greater when the area of the emission region is less, it is possible to minimize a difference in luminance between the emission regions according to a viewing angle. As a result, the display device DD according to an embodiment of the inventive concept may minimize a change in color according to a change in the viewing angle.

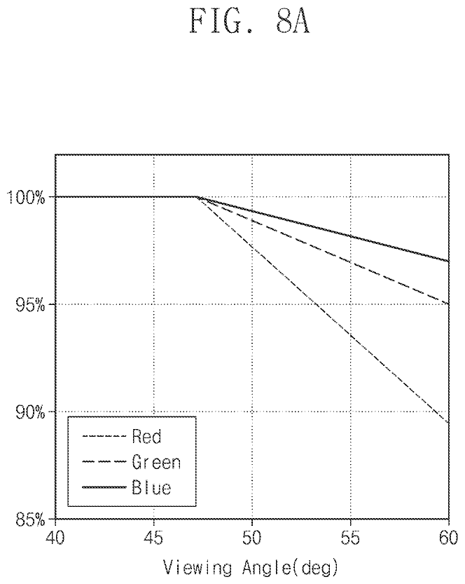

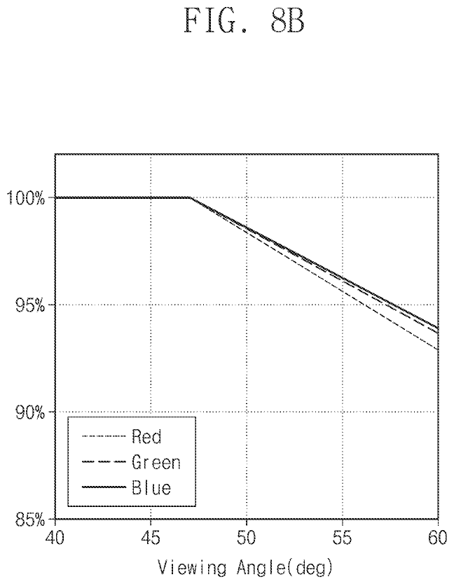

FIG. 8A is a graph illustrating a luminance ratio according to a viewing angle of the display device according to a comparative embodiment of the inventive concept. FIG. 8B is a graph illustrating a luminance ratio according to a viewing angle of the display device according to an embodiment of the inventive concept. In this specification, the viewing angle represents an angle between measurement points facing the display device DD, e.g., see FIG. 1, from a reference axis parallel to the third direction DR3. In addition, the luminance ratio according to the viewing angle was measured based on the condition that the first to third emission regions LA1, LA2, and LA3 respectively emit red light, green light, and blue light. In the display device according to the comparative embodiment of the inventive concept, the distances between the first to third emission regions and the sensing unit are the same as each other. In the display device according to the embodiment of the inventive concept, as illustrated in FIGS. 6A and 7, the distances between the first to third emission regions and the sensing unit are different from each other.

Each of FIGS. 8A and 8B show the luminance ratios of light emitted from the first to third emission regions LA1, LA2, and LA3, which were measured at different viewing angles in a direction parallel to the first direction DR1. Referring to FIGS. 6A, 7, 8A, and 8B, a decrease in luminance ratio according to color light in the first direction DR1 may occur at a viewing angle of about 47 degrees or more. The viewing angle at which the luminance ratio starts to decrease may vary depending on the design of the display device DD, e.g., see FIG. 1.

Referring to FIG. 8A, in the display device according to the comparative embodiment of the inventive concept in which the distances between the first to third emission regions and the sensing unit are the same as each other, the degrees of reduction in the luminance ratios in the first direction DR1 may be different from each other due to the differences of the first to third lengths L1, L2, and L3 of the first to third emission regions LA1, LA2, and LA3. For example, as the red light is emitted through the first emission region LA1 having the smallest length (first length L1) in the first direction DR1, the degree of reduction in the luminance ratio of the red light may be the largest among the red light, the green light, and the blue light. In addition, as the blue light is emitted through the third emission region LA3 having the largest length (third length L3) in the first direction DR1, the degree of reduction in the luminance ratio of the blue light may be the smallest among the red light, the green light, and the blue light.

On the other hand, referring to FIGS. 6A, 7, and 8B, in the display device DD according to the embodiment of the inventive concept, the first emission region LA1 having the smallest length is spaced apart from the sensing unit ML by a first distance which is the largest in the first direction DR1 and therefore has the smallest covered rate. The third emission region LA3 having the greatest length is spaced apart from the sensing unit ML by a third distance which is the smallest in the first direction DR1 and therefore has the greatest covered rate. In addition, the second emission region LA2 having a middle length is spaced apart from the sensing unit ML in the first direction DR1 by a second distance between the first and third distances and therefore has a medium covered rate. As a result, in the display device DD according to the embodiment of the inventive concept, the degree of reduction in the luminance ratio of the red light may be similar to the other colors among the red light, the green light, and the blue light according to a change in a viewing angle. Accordingly, the display device DD according to the embodiment of the inventive concept may minimize a change in color according to the change in the viewing angle.

The display device according to an embodiment of the inventive concept includes first to third emission regions and an input sensing layer including a sensing unit which has first to third openings defined therein and corresponding to the first to third emission regions. When viewed on a plane, the first distance from the first emission region to the sensing unit is less than the distance from the second emission region to the second sensing unit, and the second distance is less than the distance from the third emission region to the sensing unit. Accordingly, in the display device according to an embodiment of the inventive concept, by minimizing a difference between the covered rates of the first to third emission regions covered by the sensing unit according to a change in a viewing angle, it is possible to minimize a difference in luminance between the emission regions according to the change in the viewing angle. As a result, the display device according to an embodiment of the inventive concept has a small color difference according to the change in the viewing angle and therefore may exhibit excellent display quality.

Although the above has been described with reference to embodiments of the inventive concept, those skilled in the art or those of ordinary skill in the art will understand that various modifications and changes can be made to the inventive concept within the scope that does not depart from the spirit and technical field of the inventive concept described in the claims to be described later.

Accordingly, the technical scope of the inventive concept should not be limited to the content described in the detailed description of the specification, but should be determined by the claims described hereinafter.

What is claimed is:

1. A display device comprising:
a display panel comprising:
first emission regions comprising a first emission region;
second emission regions comprising a second emission region; and
third emission regions comprising a third emission region,
wherein the first emission regions and the second emission regions are disposed alternately in a first direction, the third emission region is spaced apart from the first emission region and the second emission region in a second direction perpendicular to the first direction, and the third emission regions are disposed along the first direction; and
an input sensing layer disposed on the display panel and comprising a sensing unit having a first opening, a second opening, and a third opening respectively exposing the first emission region, the second emission region, and the third emission region,
wherein, when viewed on a plane;
the first emission region and the sensing unit are spaced apart from each other by a first vertical distance in the first direction,
the second emission region and the sensing unit are spaced apart from each other by a second vertical distance less than the first vertical distance in the first direction, and
the third emission region and the sensing unit are spaced apart from each other by a third vertical distance less than the second vertical distance in the first direction,
wherein a first length of the first emission region in the first direction is less than a second length of the second emission region in the first direction, and
the second length is less than a third length of the third emission region in the first direction.

2. The display device of claim 1, wherein the first opening has a first opening length in the first direction,
the second opening has a second opening length in the first direction, and
the third opening has a third opening length in the first direction,
wherein an absolute value of a difference between the first length and the first opening length is less than an absolute value of a difference between the second length and the second opening length, and
the absolute value of the difference between the second length and the second opening length is less than an absolute value of a difference between the third length and the third opening length.

3. The display device of claim 1, wherein an area of the third emission region is larger than an area of the second emission region, and
the area of the second emission region is larger than an area of the first emission region.

4. The display device of claim 1, wherein the sensing unit comprises:
a first horizontal sensing part disposed between the first emission region and the second emission region and extending in the first direction;
a second horizontal sensing part disposed between adjacent third emission regions and extending in the first direction;
a first vertical sensing part extending in the second direction and disposed between the first emission region and the third emission region; and
a second vertical sensing part extending in the second direction and disposed between the second emission region and the third emission region,
wherein the first horizontal sensing part is closer to the second emission region than to the first emission region.

5. The display device of claim 4, wherein the first vertical sensing part is closer to the third emission region than the first emission region.

6. The display device of claim 4, wherein the second vertical sensing part is closer to the third emission region than the second emission region.

7. The display device of claim 4, wherein a width of the first vertical sensing part in the second direction is less than a width of the second vertical sensing part in the second direction.

8. The display device of claim 1, wherein the first emission region, the second emission region, and the third emission region respectively emit a first color light, a second color light, and a third color light, which are different from each other.

9. The display device of claim 8, wherein a wavelength range of the third color light is less than a wavelength range of the first color light and less than a wavelength range of the second color light.

10. A display device comprising:
a display panel comprising:
first emission regions comprising a first emission region;
second emission regions comprising a second emission region; and
third emission regions comprising a third emission region,
wherein the first emission regions and the second emission regions are disposed alternately in a first direction, the third emission region is spaced apart from the first emission region and the second emission region in a second direction perpendicular to the first direction, and the third emission regions are disposed along the first direction; and
an input sensing layer disposed on the display panel and comprising a sensing unit having a first opening, a second opening, and a third opening respectively exposing the first emission region, the second emission region, and the third emission region,
wherein, when viewed on a plane,
a ratio of an area of the first emission region to an area of the first opening is less than a ratio of an area of the second emission region to an area of the second opening, and
the ratio of the area of the second emission region to the area of the second opening is less than a ratio of an area of the third emission region to an area of the third opening.

11. The display device of claim 10, wherein the first emission region, the second emission region, and the third emission region respectively emit a first color light, a second color light, and a third color light, which are different from each other.

12. The display device of claim 11, wherein the first color light is a red light,
the second color light is a green light, and
the third color light is a blue light.

13. The display device of claim 10, wherein, when viewed on the plane, the area of the first emission region is less than the area of the second emission region, and the area of the second emission region is less than the area of the third emission region.

14. A display device comprising:
first emission regions comprising a first emission region having a first area;
second emission regions comprising a second emission region having a second area larger than the first area, the second emission regions being disposed alternately with the first emission regions in a first direction;
third emission regions comprising a third emission region, the third emission region having a third area larger than the second area and spaced apart from the first emission region and the second emission region in a second direction perpendicular to the first direction;
a non-emission region disposed between the first emission regions, the second emission regions, and the third emission regions;
a base substrate;
a display element layer comprising a first light emitting layer, a second light emitting layer, and a third light emitting layer disposed on the base substrate and respectively corresponding to the first emission region, the second emission region, and the third emission region; and
an input sensing layer comprising a sensing unit, which has a first opening, a second opening, and a third opening respectively corresponding to the first emission region, the second emission region, and the third emission region, the sensing unit being disposed to correspond to the non-emission region on the display element layer,
wherein, when viewed on a cross section, the sensing unit is closer to the second light emitting layer than to the first light emitting layer, is closer to the third light emitting layer than to the second light emitting layer, and is closer to the third light emitting layer than to the first light emitting layer.

15. The display device of claim 14, wherein a slope of a first tilted line which is an imaginary line extending from an edge portion of the first light emitting layer in a direction of the sensing unit adjacent to the edge portion of the first light emitting layer is less than a slope of a second tilted line which is an imaginary line extending from an edge portion of the second light emitting layer in a direction of the sensing unit adjacent to the edge portion of the second light emitting layer.

16. The display device of claim 14, wherein a slope of a second tilted line which is an imaginary line extending from an edge portion of the second light emitting layer in a direction of the sensing unit adjacent to the edge portion of the second light emitting layer is less than a slope of a third tilted line which is an imaginary line extending from an edge portion of the third light emitting layer in a direction of the sensing unit adjacent to the edge portion of the third light emitting layer.

17. The display device of claim 14, wherein a slope of a first tilted line which is an imaginary line extending from an edge portion of the first light emitting layer in a direction of the sensing unit adjacent to the edge portion of the first light emitting layer is less than a slope of a third tilted line which is an imaginary line extending from an edge portion of the third light emitting layer in a direction of the sensing unit adjacent to the edge portion of the third light emitting layer.

18. The display device of claim 14, wherein the first emission region has a first length in the first direction,
the second emission region has a second length greater than the first length in the first direction, and
the third emission region has a third length greater than the second length in the first direction.

19. The display device of claim 18, wherein the first opening has a first opening length in the first direction,
the second opening has a second opening length in the first direction, and
the third opening has a third opening length in the first direction,
wherein an absolute value of a difference between the first length and the first opening length is less than an absolute value of a difference between the second length and the second opening length, and
the absolute value of the difference between the second length and the second opening length is less than an absolute value of a difference between the third length and the third opening length.

20. The display device of claim 14, wherein the first emission region emits a red light,
the second emission region emits a green light, and
the third emission region emits a blue light.
